(19) United States
(12) Patent Application Publication
(10) Pub. No.: US 2026/0210625 A1
(43) Pub. Date: Jul. 23, 2026

(54) System and Method for Controlling a Drying Process of a Coated Film, in Particular a Battery Electrode Film

(71) Applicant: AXBIS CO.,LTD., Daejeon (KR)

(72) Inventors: Oliver Bocksrocker, Sachsenheim (DE); Wilrid Dubitzky, Leonberg (DE); Holger Joachim Mönch, Vaals (NL); Ralf Conrads, Kempen (DE); Günter Ambrosy, Stuttgart (DE); Rolf Apetz, Aachen (DE); Carsten Deppe, Aachen (DE)

(21) Appl. No.: 19/453,887

(22) Filed: Jan. 20, 2026

(30) Foreign Application Priority Data
Jan. 20, 2025 (DE) 102025101818.9

(51) Int. Cl. F26B 3/28; H01M 4/04; H01S 5/0683; F26B 25/22; H01S 5/42

(52) U.S. Cl. CPC F26B 3/28; H01M 4/0402; H01S 5/0683; F26B 25/22; H01S 5/423

(57) ABSTRACT

The present disclosure relates to a system for controlling a drying process of a coated film, the system including a sensor configured to detect one or more drying-process characteristics of the coated film, an optical radiation source module configured to emit radiation toward the coated film, and a control device configured to control the radiation of the optical radiation source module based on the drying-process characteristics. The present disclosure also relates to a corresponding method for controlling a drying process of a coated film.

### CROSS-REFERENCE TO RELATED APPLICATIONS

The present application claims the benefit of priority to German Patent Application No. 102025101818.9, filed on January 20, 2025, in the German Patent and Trade Mark Office, the entire disclosure of which is incorporated herein by reference.

### TECHNICAL FIELD

The present disclosure relates to a system and method for controlling a drying process of a coated film.

### BACKGROUND

Batteries, such as lithium-ion batteries, are essential for use in applications such as electric vehicles and mobile devices. A key component of such batteries is an electrode film, which consists of a metal carrier such as aluminum or copper, on which a layer including an active material, a binder, and a solvent is coated. After coating, the film is dried to evaporate the solvent and to form a uniform and stable layer.

The drying process is generally performed as a roll-to-roll process that guides the continuously coated film through a drying zone. For this purpose, hot air blowers or infrared radiators may be used, which enable uniform area irradiation of the absorbing surface of the coating. The layer is processed with a constant drying output or a uniform radiation intensity while the transport of the web is kept constant.

### SUMMARY

The inventors of the present disclosure recognized that undesirably high laser radiation intensity may occur, particularly in roll-to-roll processes using laser-based radiation sources. For example, this phenomenon may occur when highly reflective uncoated regions of the film pass under the laser. Such uncoated regions strongly reflect laser light, which may cause significant heating, particularly when the laser module itself and the surrounding environment also have high reflectivity with respect to the laser radiation used. Such increased radiation intensity represents a serious risk, as it can damage not only the workpiece being processed (e.g., a battery electrode film) but also equipment components and the laser module itself. Additionally, moisture pockets (wet regions) of the coating may have increased reflectivity compared to dried regions.

The present disclosure is directed to providing an improved system and method for a drying process of a coated film.

According to one aspect of the present disclosure, a system for controlling a drying process of a coated film is provided, the system including a sensor configured to detect one or more drying-process characteristics of the coated film, an optical radiation source module configured to emit radiation toward the coated film, and a control device configured to control the radiation of the optical radiation source module based on the drying-process characteristics.

According to another aspect of the present disclosure, a corresponding method for controlling a drying process of a coated film is provided.

Certain preferred embodiments of the present disclosure are defined in the dependent claims. It is understood that the method may have similar and/or identical preferred embodiments as the system, particularly as defined in the dependent claims and disclosed herein.

### BRIEF DESCRIPTION OF THE DRAWINGS

The above and other aspects, features, and advantages of the present disclosure will become apparent from the detailed description of the following aspects in conjunction with the accompanying drawings, in which:

FIG. 1 is a schematic side view of a system for drying a coated film;

FIG. 2 is a schematic plan view of the system of FIG. 1;

FIG. 3 is a schematic side view along a transport direction of a coated film;

FIG. 4 is a schematic diagram of a second embodiment of a system for drying a coated film;

FIG. 5 is a schematic diagram of a third embodiment of a system for drying a coated film;

FIG. 6 is a schematic diagram of a fourth embodiment of a system for drying a coated film;

FIG. 7 is a schematic diagram of a fifth embodiment of a system for drying a coated film;

FIG. 8 is a schematic diagram of a VCSEL module shown in FIG. 7;

FIG. 9 is a schematic diagram of a VCSEL module with photodiode chips integrated therein; and

FIG. 10 is a flowchart of a method for controlling a drying process of a coated film.

### DETAILED DESCRIPTION

Hereinafter, some embodiments of the present disclosure will be described in more detail. However, the following embodiments are provided merely as references for describing the present disclosure in detail, and the present disclosure is not limited thereto and may be implemented in various forms.

Unless otherwise defined, all technical and scientific terms used in the present disclosure have the same meanings as commonly understood by those skilled in the art of this application. The terms "include," "comprise," and any variations thereof used in the specification of this application are intended to encompass non-exclusive inclusion.

In the description of the present disclosure, it shall be noted that, unless explicitly defined or limited otherwise, terms such as "mounted," "interconnected," "connected," etc., should be interpreted broadly. For example, they may be fixed connections, detachable connections, or integral connections, and they may be directly interconnected, or indirectly interconnected through intermediate media. Those of ordinary skill in the art should understand the specific meanings of the above-mentioned terms in the present application according to the specific situation.

The present disclosure may use ordinal numbers such as "first," "second," "third," etc., to refer to elements, and it should be noted that, unless explicitly indicated otherwise, these are merely used to distinguish between different elements and do not imply that the mentioned elements are necessarily provided in the indicated order in terms of time, space, or other aspects.

For purposes of this application and the claims, using the exemplary phrase "at least one of: A; B; or C" or "at least one of A, B, or C," the phrase means "at least one A, or at least one B, or at least one C, or any combination of at least one A, at least one B, and at least one C. Further, exemplary phrases, such as "A, B, and C", "A, B, or C", "at least one of A, B, and C", "at least one of A, B, or C", etc. as used herein may mean each listed item or all possible combinations of the listed items. For example, "at least one of A or B" may refer to (1) at least one A; (2) at least one B; or (3) at least one A and at least one B.

The present disclosure is based on the concept of selectively adjusting laser output during a drying process in order to enable a uniform drying process of coated films, for example, battery electrode films. Alternatively or additionally, damage to films, equipment components, or laser modules due to very high radiation intensity, reflections from uncoated regions, or excessive heating may be prevented.

The inventors of the present disclosure recognized that coating characteristics of films may be non-uniform in roll-to-roll drying processes for battery electrode coatings. Prior to the drying process, coatings may vary in important parameters such as layer thickness, composition, and moisture content, making uniform processing difficult. Additionally, intentional variations in coating characteristics are possible, for example structuring or a sequential arrangement of coated and uncoated regions. When films are dried with a constant radiation intensity, so-called moisture pockets may form due to differences in moisture content, where such regions locally retain higher residual moisture that impairs drying results.

Additionally, there is a risk of overheating due to non-uniform energy absorption, which may damage sensitive coatings. Furthermore, heat flow at coating edges may differ from that in central areas, thereby increasing the likelihood of thermal stress and other irregularities. Accordingly, natural non-uniformities in the coating process, such as variations in layer thickness and moisture content, may create additional challenges for precise and non-damaging drying of battery electrode films. These factors may impair uniform quality and impose additional demands on the equipment used.

One approach to addressing the above-described issues is based on detecting one or more drying-process characteristics by one or more sensors arranged in or near a laser module. The sensors may also be configured to detect laser radiation emitted by an optical radiation source module that has been reflected once or multiple times. A control device may be configured to reduce laser intensity to non-hazardous levels and to reactivate laser operation below predefined threshold values. This may enable automatic, simple, and safe prevention of damage to films, equipment, and the laser module itself due to excessively high laser intensity.

In particular, highly reflective uncoated regions of the film that can potentially cause dangerous laser radiation intensity peaks may be controlled and processed in a safe manner to avoid damage to a workpiece, the laser module, and surrounding equipment components. Alternatively or additionally, disadvantages of non-uniform coatings may be compensated for by drying adjusted to local conditions of the film. Additionally, spatially uniform heat distribution may be promoted to reduce thermal stress at edges and to ensure uniform coating quality.

An additional advantage may be that battery film drying according to the present disclosure can shorten drying lines compared to conventional convection ovens. Spatial and temporal output distribution may ensure higher process stability and enable precise adjustment to the condition of the film, thereby preventing the formation of moisture pockets or overheating. Using optical sensors such as thermal imaging cameras or photodetectors, at different wavelength ranges as needed, may enable fast and spatially resolved detection of relevant parameters such as moisture, reflection, layer thickness, or temperature. This may enable direct or indirect monitoring of drying progress and correspondingly adjusted control. PID-based or AI-based control may increase process efficiency and enhance yield of the overall process.

Another aspect may involve targeted pre-drying of coatings before the actual drying process in subsequent drying ovens. Such pre-drying may induce rapid and efficient homogenization so that coatings enter the drying ovens with uniform characteristics.

According to the present disclosure, the system for controlling the drying process of coated films includes a sensor. The observation wavelength range of process emissions may be in the 300-3000 nm range, particularly thermal radiation in the range above 750 nm, while wavelengths of a processing beam in the 800-1100 nm range, particularly 850 nm, 940 nm, 980 nm, 1030 nm, or 1070 nm, that is, radiation of the optical radiation source module, may be blocked or filtered. The sensor may include correspondingly adjusted bandpass filters, band-stop filters, or long-pass filters in the 750-3000 nm range, particularly with a bandwidth of 500 nm or less.

The sensor may be one or more photodiodes and/or thermal sensors. The sensor may be configured to detect sensor signals containing information about one or more characteristics of the drying process of the coated film. Possible detectable drying-process characteristics may include, for example, surface gloss, that is, reflection of illumination, irradiation, and/or ambient light.

The sensor(s) may preferably be arranged to reliably detect radiation reflected from a workpiece, for example, a battery electrode film, while being exposed as little as possible directly to radiation emitted by the optical radiation source module during normal operation. The reflected radiation may be single-reflected radiation or multiple-reflected radiation.

Additionally, the system according to the present disclosure includes at least one optical radiation source module, such as a laser or a laser module. The coated film may be a battery electrode film. This film may include, for example, copper or aluminum as a substrate or carrier film, with a thickness typically of 5–30 μm, particularly 6–15 μm, and may include nickel, manganese, cobalt, lithium iron phosphate, or graphite as a coating, with a thickness typically of 20–200 μm, particularly 50–150 μm. The coated film may be moved over guide elements such as rollers or air cushions in a transport direction relative to the sensor and the optical radiation source module. One or more sensors per laser or laser module may be provided, which may be arranged inside or next to the laser module.

The optical radiation source module may be a laser diode module, particularly a vertical cavity surface-emitting laser (VCSEL) module including a plurality of VCSELs, with a length of 300–1800 mm, particularly 500–1700 mm, and a width of 50–500 mm, particularly 80–400 mm. At least two VCSEL modules may be arranged continuously. The number of VCSEL chips per module may be in the range of 100–50,000, particularly in the range of 1,000–10,000. The laser output per VCSEL chip may be in the range of 1–20 W, typically 2 W. The laser output per module may be in the range of 2 kW–50 kW, typically 4 kW–40 kW. An advantageous design may include dividing the module into a plurality of regions or zones that may be individually driven to control local radiation intensity under the module. The number of zones per module may be in the range of 4–400, particularly in the range of 10–100.

The optical radiation source module is configured to emit radiation toward the coated film. The module may include one or more direct diode lasers and/or fiber lasers, particularly VCSELs. The optical radiation of the module may be in the 800–1300 nm wavelength range, particularly in the 900–1170 nm wavelength range.

The system further includes a control device configured to control the radiation of the optical radiation source module based on characteristics of the drying process. The control device may include intensity control and may include functionality for turning individual VCSELs or entire VCSEL modules on or off, and may be implemented, for example, as a PID controller or an AI controller. The system may have closed-loop process control.

The sensor may be configured to detect drying-process characteristics of the coated film at one measurement time point and/or measurement position, and the optical radiation source module may be configured to emit radiation toward the coated film at one control time point and/or control position. The control time point and/or position may be before, after, or the same as the measurement time point and/or position. Since the manufacturing process of battery electrode films is typically performed continuously, measurement may be performed at a position of the battery electrode film that has already passed through the optical radiation source (laser). Nevertheless, control may be performed, for example, by adjusting the intensity of the radiation source based on the measurement to provide adjusted radiation for subsequent sections of the battery electrode film.

The sensor may be a sensor having spatial and temporal resolution, that is, a sensor that resolves spatially and temporally, particularly a camera or a photodiode array. The sensor may include one or more complementary metal-oxide-semiconductor (CMOS) sensors, charge-coupled device (CCD) sensors, and/or indium gallium arsenide (InGaAs) sensors. The camera may be, for example, a thermal imaging camera. In this case, the thermal imaging camera may detect temperature differences on the film surface. InGaAs photodiode arrays may determine moisture distribution and solvent concentration using specific wavelengths in the infrared range.

In a preferred embodiment, the optical radiation source module may be intensity-controlled in a position-dependent manner across a width of the coated film, between edge regions thereof. This enables targeted control of spatial output distribution, particularly in combination with additional spatially resolving sensors.

In the case of battery electrode films, edge regions are defined as regions located at the outer edges of the film in a direction orthogonal to the transport direction. Therefore, these regions include outer portions of the film arranged laterally with respect to the direction of movement during transport. Heat flow may behave differently in these edge regions compared to inner regions.

In this embodiment, for example, precisely these edge regions may be irradiated with a different intensity than the central region of the film. Additionally, other non-uniformities caused by, for example, different layer thicknesses may also be considered. As a result, process stability may be improved by preventing moisture pockets or overheating.

In another embodiment, the optical radiation source module may be intensity-controlled in a time-dependent manner taking into account the transport speed of the coated film. This enables targeted control of temporal output distribution. For example, such control may be performed in the form of subsequent control during the drying process. For example, a sensor may be arranged in front of the optical radiation source module, and the intensity of the optical radiation source module may be adjusted with a time delay considering the transport speed of the coated film, such that the film region previously measured by the sensor is irradiated with an adjusted intensity when the film region passes through the optical radiation source module. Additionally, it is also possible that at least two sensors may track drying of the battery film over time and control output of the optical radiation source module based on information obtained by tracking the drying. There may be an advantage that process stability is improved by preventing moisture pockets or overheating.

In one embodiment, the sensor in the system may be disposed upstream of or downstream of the optical radiation source module when viewed along the transport or conveyance direction of the coated film. In the former case, the sensor first detects drying characteristics, and based on information obtained by the sensor, the subsequent optical radiation source module is controlled. As a result, radiation may be directly adjusted in regions where detected moisture pockets or other non-uniformities exist.

When the sensor is arranged downstream of the optical radiation source module as in the latter case, conclusions may be drawn from the detected drying-process characteristics about the drying progress up to that point and may be used for targeted control of the upstream optical radiation source module. Downstream measurement may seem counterintuitive. However, the inventors of the present disclosure recognized that measurement downstream of the radiation source may achieve improved measurement accuracy or reduce the risk of highly reflective regions. This may provide the advantage of more precise control, particularly when measurement accuracy is low due to reflection from wet surfaces before drying.

Another possibility is to arrange a sensor between two optical radiation source modules to monitor drying-process characteristics and to control upstream and/or downstream radiation sources. The system may include a first optical radiation source module and a second optical radiation source module. When viewed along the transport direction of the coated film, the sensor may be arranged between the first and second optical radiation source modules. This may provide the advantage that, in particular, after potentially uncontrolled pre-drying by the first optical radiation source module, the sensor may detect drying progress of the film, and then controlled subsequent drying may be performed based on previously detected sensor data. The system may include more than two optical radiation source modules. For example, a drying line may include at least 5 optical radiation source modules, particularly at least 10 or at least 50 optical radiation source modules, and for example, may include 100 optical radiation source modules. One or more optical radiation source modules may be arranged upstream of the sensor. One or more optical radiation source modules may be arranged downstream of the sensor.

In another embodiment, the sensor may be a VCSEL module with photodiode arrays at least partially integrated therein. Photodiodes and VCSELs may be arranged alternately, particularly for continuous monitoring of the drying process. In this case, photodiode chips and VCSEL chips may be arranged alternately individually or in groups. Different photodiodes, such as CCD, CMOS, or InGaAs types, may be adjusted for specific wavelength ranges, thus enabling measurement in different spectral ranges. Preferably, the same sensor type and wavelength range are used for efficient manufacturing.

Preferably, the optical radiation source module may include a plurality of integrated sensors. Additionally, the optical radiation source module may be configured to have a plurality of individually controllable or adjustable regions. This may enable precise and individual control of drying for individual regions of the battery film.

In a preferred embodiment, the sensor is configured to detect an intensity, particularly an intensity of radiation emitted by the optical radiation source module or an intensity of radiation back-reflected to the optical radiation source module. The control device is configured to reduce radiation of the optical radiation source module when the sensor detects an intensity exceeding an upper threshold value (upper threshold). Accordingly, when the measured intensity exceeds the upper threshold value, radiation may be reduced by dimming or turning off the module. The purpose of this is to adjust the intensity so that exceeding the threshold is avoided or limited to non-hazardous levels. This may ensure that workpieces such as battery electrode films, lasers, or surrounding equipment are not damaged. When the intensity falls below this threshold again, the optical radiation source module may be controlled upward again to nominal process values. The upper threshold value may be a protective threshold that may be provided in addition to nominal control values of the drying process.

In one embodiment, the control device may be configured to reduce the output of the optical radiation source module to a predefined minimum value when the sensor detects an intensity exceeding the upper threshold value. Radiation of the optical radiation source module at the predefined minimum value may be used as measurement radiation for detecting one or more drying-process characteristics by the sensor. That is, as soon as the detected intensity exceeds the upper threshold value or a protective threshold, the output may be reduced to a minimum output. This may provide rapid protective functionality. This type of control may be provided in addition to controlling the optical radiation source module to a nominal output or a desired drying level. However, radiation is not completely turned off. Instead, radiation at the predefined minimum value is used as measurement radiation. This may be used, for example, to determine when reflectivity of the material returns to normal values. When the intensity falls below a second, significantly lower threshold value, the optical radiation source module may be controlled upward again to a nominal output or even a full output to achieve nominal process values.

The control device may be configured to operate the optical radiation source module in a pulse mode. Particularly, the control device may be configured to operate the optical radiation source module in a pulse mode such that a time-averaged value of an output of the optical radiation source module is reduced when the sensor detects an intensity exceeding the upper threshold value. Radiation of the optical radiation source module during pulses may be used as measurement radiation for detecting one or more drying-process characteristics by the sensor. For example, the optical radiation source module may emit pulsed radiation when the sensor measures an intensity exceeding the upper threshold value until the intensity falls below the threshold value again. Alternatively, control may be performed by pulsing, such that when intensity exceeds the threshold value, the laser is completely turned off. At short intervals, the laser output may be reactivated and immediately deactivated again while the threshold-exceeding condition persists. When the intensity falls below the threshold value, the laser may be operated again at, for example, a nominal output or a normal output for the drying process.

The sensor, the optical radiation source module, and the control device may be integrated in a common module housing. Particularly, the optical radiation source module may be a VCSEL module having a plurality of VCSELs. The control device may be part of a VCSEL laser driver integrated into the common module housing. In this embodiment, the proposed system may be understood as an optical radiation source module having a jointly integrated control device and one or more jointly integrated sensors. An advantage of this approach may be that the drying system may be more readily mounted or retrofitted. Particularly, safety-related functions for radiation output limitation may be provided directly inside the module by the control device. Therefore, even if external control signals fail, safer operation of the drying system may continue to be ensured.

Preferably, the sensor may be configured to detect reflection, from the coated film, of radiation emitted by the optical radiation source module. Alternatively or additionally, reflectivity of the workpiece may also be detected by a separate measurement device or a camera, particularly upstream of the laser, that is, before regions of the workpiece showing strong reflection reach the laser. The control device may be configured to limit or resume radiation of the optical radiation source module at precise time points. This may increase operational safety of the entire process.

The sensor may be a spatially resolving sensor configured to detect regions exhibiting stronger reflection of radiation. The control device may be configured to reduce radiation of the optical radiation source module toward regions showing stronger reflection. This may prevent damage to the laser module due to excessively strong back-reflection from regions having high moisture content, for example. Instead of increasing output to achieve stronger drying in wet regions, it is also possible to selectively reduce output. Alternatively or additionally, reflectivity of the workpiece may be detected by a separate measurement, for example by a sensor or a camera positioned upstream of the laser. This measurement may enable radiation output to be limited, or subsequently re-permitted, at a precise time before highly reflective regions reach the optical radiation source module. In this way, damage to workpieces or films, equipment, and the laser module itself due to excessively high laser intensity may be prevented automatically, simply, and safely.

In another embodiment, a distance between the coated film and the optical radiation source module may be less than 200 mm. Particularly, the distance may be greater than 100 mm. Smaller working distances enable more precise application of radiation. Working distances between 100mm and 200mm may be considered particularly advantageous because they enable, on one hand, precise application of radiation with spatial resolution. On the other hand, at such working distances, occasional failures of individual radiation sources, for example individual VCSELs, may be compensated by overlapping radiation areas of adjacent radiation sources. However, working distances less than 100mm or greater than 200mm are also possible and are not excluded.

Preferably, the sensor may be configured to detect surface gloss of the coated film. Gloss is an optical property in which a surface reflects light in a wholly or partially specular manner. Gloss may occur when illumination is sufficiently directional and the surface reflects specularly. Reflection of illumination, irradiation, and/or ambient light may be used for measurement. In the case of back-reflection from matte surfaces, the optical radiation source module may be operated at a higher output, for example, because radiation is only diffusely reflected and returns to the optical radiation source module at a lower intensity. On the other hand, on surfaces with strong surface gloss, radiation may be at least partially specularly reflected and return to the optical radiation source module at a higher intensity.

In another embodiment, the system further includes a secondary radiation source configured to emit radiation toward the coated film. The radiation emitted by the secondary radiation source may also be referred to as secondary radiation. A radiation spectrum of the secondary radiation source may be different from a radiation spectrum of the optical radiation source module, enabling additional illumination in a visible-light spectrum range or an infrared spectrum range, for example. The sensor may be configured to measure reflection, from the battery film, of radiation emitted by the secondary radiation source. This may enable drawing additional conclusions about drying characteristics of the battery film, further improving accuracy of the system.

In another embodiment, control of radiation of the optical radiation source module by the control device may include evaluation and optimization using artificial intelligence systems, particularly machine learning-based AI systems. Such AI-based data processing may be performed using, for example, convolutional neural networks (CNNs), semantic segmentation techniques, and neural network architectures such as U-Net.

In a preferred embodiment, the drying-process characteristics include at least one of drying degree, moisture content, radiation intensity and/or radiation spectrum, radiation reflection intensity and/or radiation reflection spectrum, an amount of evaporated solvent, thermal distribution, layer thickness, surface condition, or defects of the coated film. The drying degree may indicate progress of solvent removal from the film. The moisture content may indicate an amount of residual moisture remaining in the layer, thereby enabling identification of moisture pockets, for example. The radiation intensity may indicate radiation output per unit area. The radiation spectrum may describe a wavelength distribution of the emitted radiation. The radiation reflection intensity and the radiation reflection spectrum may provide information regarding absorption and reflection of radiation by the film. The amount of evaporated solvent may enable conclusions regarding a drying rate and drying efficiency. The thermal distribution may relate to uniformity of a temperature distribution across the film. The layer thickness and the surface condition may be used to detect defects of the coated film and may be determined using X-rays or microwaves. Additionally, process emissions emitted from evaporated materials may be detected, for example, in a visible-light (VIS) range. Alternatively or additionally, reflection of a processing beam may be detected. Accordingly, based on signals from the sensor, the system may recognize positions at which non-uniformities exist in the coated film and may control one or more radiation source modules in a targeted manner at those positions. A general advantage of these techniques is that drying progress may be monitored directly or indirectly.

The system may include a plurality of sensors (or a plurality of sensor regions of one sensor). When a plurality of sensors are used for one or more optical radiation source modules, different evaluation approaches for the sensor signals are possible. One example is that the highest signal (i.e., the highest local intensity) is used to dim the entire optical radiation source module. Another example is that average values of the sensors are used. In this case, the system becomes less sensitive to local reflections from small areas.

When optical radiation source modules are divided into different zones and one or more sensors are assigned to each zone, control or limitation may be performed separately (locally) for each zone.

The moisture content before entering the drying oven is typically hundreds to thousands of ppm (parts per million). The purpose of the drying process is to reduce this value to at least one-tenth, so that residual moisture after drying is markedly lowered. Drying by one or more optical radiation source modules may shorten drying lines compared to convection ovens.

The system may be configured to recognize uncoated regions. The control device may be configured to adjust radiation emitted by the optical radiation source module based on recognition results, particularly to reduce the radiation in uncoated regions. In this case, presence or absence of coating may also be understood as a drying-process characteristic of the coated film within the meaning of the present disclosure. The film may include coated regions and uncoated regions, particularly for material-saving manufacturing methods. Intentional structuring of coating may be provided. In uncoated regions, radiation emitted by the optical radiation source module may be reduced or turned off. This may not only improve energy efficiency but may also reduce a risk of undesirably strong back-reflection from uncoated film regions showing strong reflection. Additionally, it is also possible to reduce radiation in uncoated regions but not turn the radiation off completely. The system may be configured such that the reduced radiation continues to be used by the sensor as measurement radiation for detecting one or more drying-process characteristics.

The features described above and the features to be further described below may be used not only in the specified combinations but also in other combinations or individually, without departing from the scope of the present disclosure.

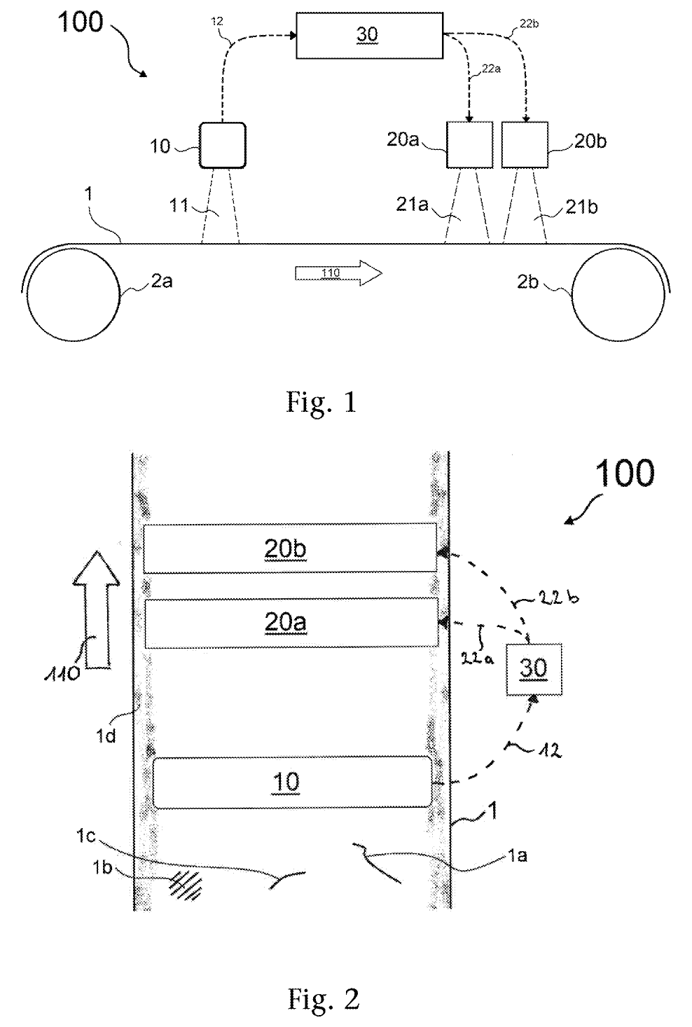

FIG. 1 shows a schematic diagram in side view of a system 100 for drying a coated film, particularly a battery electrode film 1, which is moved in a transport direction 110 by transport means 2a, 2b. The battery electrode film 1 may be an anode film or a cathode film. Possible substrate materials may include, for example, copper, aluminum, iron, or lithium, and possible coating materials may include, particularly, nickel, manganese, cobalt, lithium iron phosphate, or graphite.

The transport means 2a, 2b may be, for example, rollers or air cushions. The transport means 2a, 2b may actively contribute to transport of the battery electrode film 1 or may be designed as passive guide elements. In any case, however, they ensure that the film maintains its path and is guided through the system 100. The transport means 2a, 2b for passing the coated film under an optical radiation source module 20 may also be part of the system 100.

Furthermore, the system 100 includes a sensor 10 as a measuring device and two optical radiation source modules, here vertical cavity surface-emitting laser (VCSEL) modules 20a, 20b. Only one optical radiation source module may be provided, or additional optical radiation source modules may be further provided. As the sensor 10, photodiode arrays and thermal imaging cameras or the like may be used. The sensor 10 is configured to detect one or more drying-process characteristics of the battery electrode film 1. The drying-process characteristics represent the drying progress in the film region 11 detected by the sensor. The sensor 10 may preferably detect individual sub-regions of the film within the detected film region 11 separately. The smaller these individual sub-regions are, the more accurate the measurement becomes, and the more precisely non-uniform positions of the battery electrode film 1 may be detected.

The VCSEL modules 20a, 20b are configured to emit radiation 21a, 21b toward the battery electrode film 1 to contribute to drying of the film. The optical radiation source module may provide various possibilities for drying coated films by using particularly infrared radiation, particularly near-infrared radiation having, for example, a wavelength of 980 nm, to enable efficient evaporation of solvents and uniform drying of coatings. In the embodiment shown in FIG. 1, the optical radiation source module is a VCSEL module 20 using laser radiation in the near-infrared range, which supports the drying process of the battery electrode film 1 in a targeted and energy-efficient manner.

Furthermore, the system 100 includes a control device 30, which receives sensor signals 12 containing information about one or more drying-process characteristics from the sensor 10, processes the sensor signals 12, and based on the sensor signals 12 controls the radiation 21a, 21b emitted by the VCSEL modules 20a, 20b via control signals 22a, 22b. The control device 30 may be implemented as a processor that processes the drying-process characteristics with various evaluation methods. In particular, the control device 30 may compare the received data with threshold values and calculate appropriate control for the VCSEL modules based on that information. The control may then be performed, for example, by dimming, pulsing, or turning off individual VCSELs, VCSEL regions, VCSEL groups, or entire VCSEL modules 20a, 20b.

FIG. 2 shows a schematic diagram of the system of FIG. 1 in a plan view. As exemplarily shown, the battery electrode film 1 may have wrinkles 1a, moisture pockets 1b, waves 1c, and wet edges 1d. These non-uniformities may be detected by the sensor 10 and may be transmitted to the control device 30 through sensor signals 12. The control device may then transmit control signals 22a , 22b to the VCSEL modules 20a, 20b and adjust radiation emitted by the VCSEL modules in response to the previously detected non-uniformities.

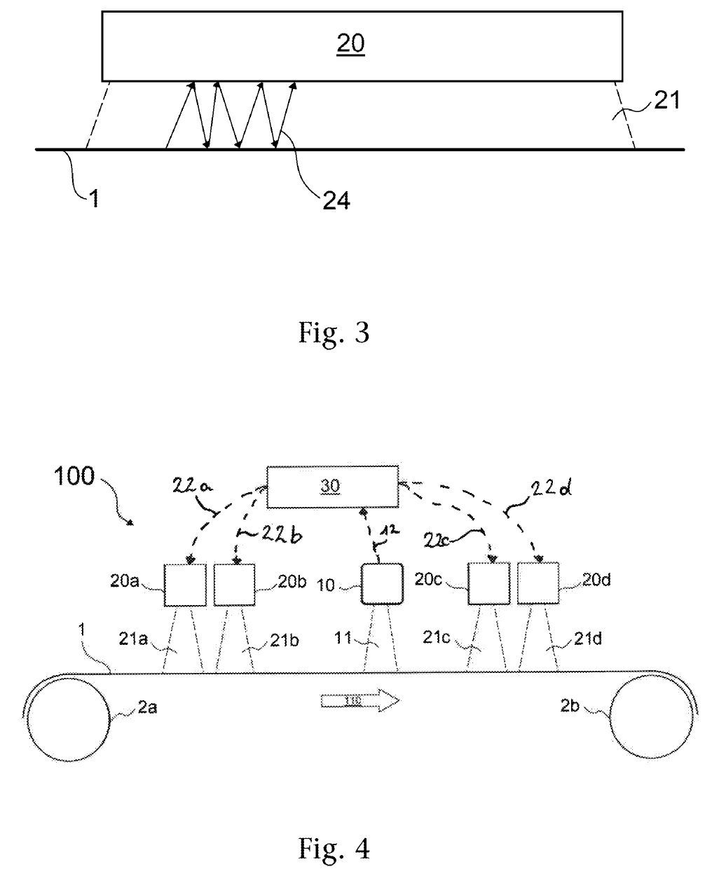

FIG. 3 shows a schematic side view along the transport direction of the coated film. As shown in FIG. 3, the VCSEL module 20 emits radiation 21 toward the battery electrode film 1 for drying. However, multiple reflections 24 may occur, which may cause strong heat generation and damage both the battery electrode film 1 and the VCSEL module 20. By controlling the VCSEL module 20 by, for example, dimming, pulsing, or turning off the VCSEL module 20, the illustrated heat generation may be suppressed. In this case, the reflection behavior of the battery electrode film may depend particularly on the drying-process characteristics. For example, moisture pockets may cause strong back reflection, and without appropriate control and reduction of radiation output, parts of the system or the battery electrode film 1 may be damaged.

FIG. 4 shows a schematic diagram of a second embodiment of the system 100 in which the sensor 10 is positioned between first optical radiation source modules, here VCSEL modules 20a, 20b, and second optical radiation source modules, here VCSEL modules 20c, 20d. Additional optical radiation source modules 20a, 20b may be positioned upstream of the sensor 10 and/or additional optical radiation source modules 20c, 20d may be positioned downstream of the sensor 10. This configuration provides the possibility of performing controlled or uncontrolled pre-drying of the battery electrode film 1, then measuring the drying progress, and thereafter controlling only the radiation of the VCSEL modules 20c, 20d downstream in the transport direction 110, or also controlling the radiation of the upstream VCSEL modules 20a, 20b, or controlling both. This embodiment has the advantage that measurement accuracy may be improved due to the lower reflectance of dry regions compared to wet regions, since the battery electrode film 1 may already be pre-dried to some extent before measurement by the sensor 10.

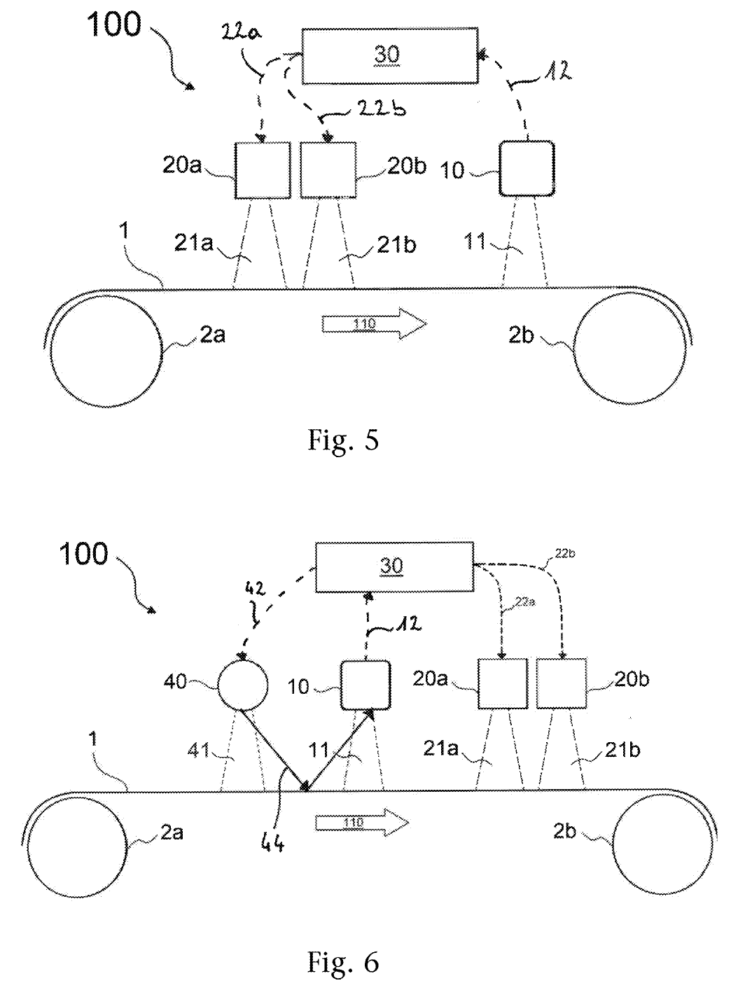

FIG. 5 shows a schematic diagram of a third embodiment of the system 100 in which the sensor 10 is positioned downstream when viewed in the transport direction 110. In this case, conclusions may be drawn from detected drying-process characteristics regarding drying progress up to that point and may be used for targeted control of upstream VCSEL modules 20a, 20b.

FIG. 6 shows a schematic diagram of a fourth embodiment of the system 100. The system 100 further includes a secondary radiation source 40 that emits secondary radiation 41 toward the battery electrode film 1. The radiation spectrum of the secondary radiation source differs from the radiation spectrum of the VCSEL module and may be, for example, in the visible-light (VIS) or near-infrared (NIR) range. The sensor 10 may then collect information about a current drying progress of the film by separately detecting reflection 44 of the secondary radiation 41 from the battery electrode film 1. The sensor signal 12 may therefore alternatively or additionally include information about the reflection 44, and the control device 30 may derive conclusions regarding the drying-process characteristics of the battery electrode film 1 therefrom. Where appropriate, the control device 30 may also directly or indirectly control the secondary radiation source 40 and the radiation 41 emitted by the secondary radiation source, as illustrated in FIG. 6.

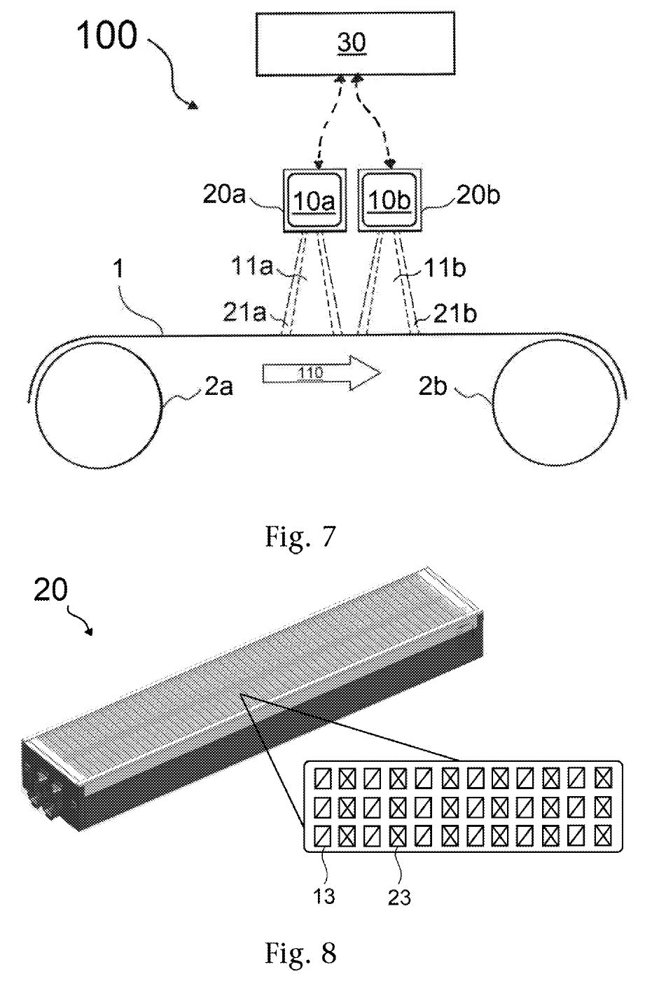

FIG. 7 shows a schematic diagram of a fifth embodiment of the system 100 in which the sensor 10 or a plurality of sensors for continuous monitoring of the drying process are integrated into the VCSEL module 20. An example design of the VCSEL module in this embodiment is shown in FIG. 8.

FIG. 8 shows a schematic diagram of the VCSEL module 20 shown in FIG. 7, in which photodiodes functioning as the sensor 10 and VCSELs are alternately arranged in groups. Photodiode chips 13 and VCSEL chips 23 (shown only once in FIG. 8 but applicable to all rectangles of the same pattern) are arranged alternately side by side in columns. As the battery electrode film 1 passes beneath this module, drying-process characteristics, and thus drying progress, may be continuously detected by the photodiode chips 13. The resulting signal may then be evaluated by the control device 30 (not shown in FIG. 8), such that the VCSEL chips 23 are driven and controlled individually or in groups depending on a radiation intensity required in each region of the battery electrode film 1. A plurality of VCSEL chips 23 may be provided per photodiode chip 13. For example, photodiode chips 13 may be provided only every 3 rows or 5 rows. Furthermore, other arrangements of VCSEL chips 23 and photodiode chips 13 may be selected. For example, one photodiode chip 13 may be surrounded by a plurality of VCSEL chips 23. Measurement by one photodiode chip 13 may be used to control one or more surrounding VCSEL chips 23.

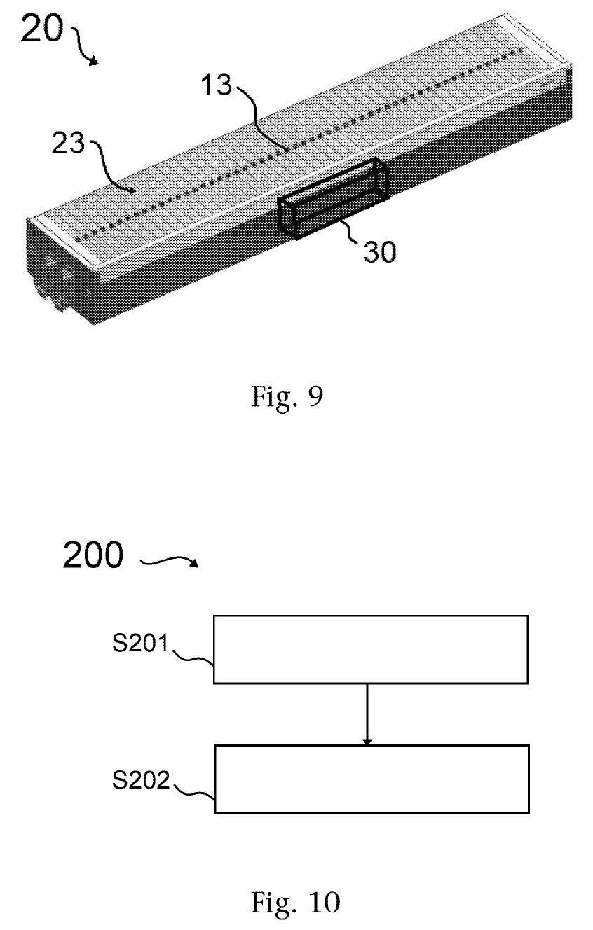

FIG. 9 shows a VCSEL module 20 with photodiode chips 13 integrated therein. As a modification of the VCSEL module shown in FIG. 8, the photodiode chips 13 in this embodiment are arranged at a central portion of the module over the entire length of the module. Although shown only once, this arrangement applies to all indicated positions along the center line.

As illustrated in FIG. 9, the sensor 10, which includes a plurality of photodiode chips 13, an optical radiation source module, which includes a plurality of VCSEL chips 23, and the control device 30 may be integrated into a common module housing. Accordingly, FIG. 9 illustrates a possible design of the system 100 including the optical radiation source module (here, the VCSEL module 20 having a plurality of VCSEL chips 23), the sensor 10 (here, the photodiode chips 13), and the control device 30. The control device 30 may be part of a VCSEL laser driver integrated into the common module housing.

FIG. 10 shows a flowchart of a method 200 for controlling a drying process of a coated film. In S201, one or more drying-process characteristics of the coated film are detected. The drying-process characteristics may include at least one of drying degree, moisture content, radiation intensity and/or radiation spectrum, radiation reflection intensity and/or radiation reflection spectrum, an amount of evaporated solvent, thermal distribution, layer thickness, surface condition, or defects of the coated film. In S202, the radiation of an optical radiation source module 20 is controlled based on the drying-process characteristics.

Each element may be configured as described in more detail above. Features of one or more embodiments may be combined. Similar elements are indicated by the same reference numerals. To avoid repetition, differences or additions are emphasized in further embodiments.

In summary, aspects of the approach proposed herein may provide an improved system for drying a coated film. With the present approach, it is possible to target-adjust radiation (for example, laser output) during the drying process to compensate for coating characteristic variations of battery electrode films. By detecting these characteristics with sensors, laser intensity may be flexibly controlled and compensated in non-uniform regions such as, for example, regions having differences in layer thickness or moisture content. At the same time, according to aspects of the present disclosure, the risk of overheating may be reduced by precisely tailoring energy input to the requirements of each film region.

What is claimed is:

1. A system for controlling a drying process of a coated film, the system comprising:
a sensor configured to detect one or more drying-process characteristics of the coated film;
an optical radiation source module configured to emit radiation toward the coated film; and
a control device configured to control the radiation of the optical radiation source module based on the drying-process characteristics.

2. The system of claim 1, wherein the optical radiation source module is a laser diode module, the laser diode module being a VCSEL module comprising a plurality of VCSELs.

3. The system of claim 1, wherein the sensor has spatial and temporal resolution and is a camera or a photodiode array, and wherein the sensor is configured to detect reflection, from the coated film, of radiation emitted by the optical radiation source module, or to detect gloss of a surface of the coated film.

4. The system of claim 1, wherein an intensity of radiation emitted by the optical radiation source module is controllable in a position-dependent manner across a width of the coated film, between edge regions thereof.

5. The system of claim 1, wherein an intensity of radiation emitted by the optical radiation source module is controllable in a time-dependent manner taking into account a transport speed of the coated film.

6. The system of claim 1, wherein the sensor is disposed upstream of or downstream of the optical radiation source module as viewed along a transport direction of the coated film.

7. The system of claim 1, wherein the system comprises a first optical radiation source module and a second optical radiation source module, and wherein the sensor is disposed between the first optical radiation source module and the second optical radiation source module as viewed along a transport direction of the coated film.

8. The system of claim 1, wherein the optical radiation source module is a VCSEL module in which a photodiode array is integrated, wherein photodiodes and VCSELs are arranged alternately.

9. The system of claim 1, wherein a plurality of sensors are integrated into the optical radiation source module, and wherein the optical radiation source module comprises a plurality of individually controllable zones.

10. The system of claim 1, wherein the sensor is configured to detect an intensity, and wherein the control device is configured to reduce radiation emitted by the optical radiation source module when the sensor detects an intensity exceeding an upper threshold value.

11. The system of claim 10, wherein the control device is configured to reduce an output of the optical radiation source module to a predefined minimum value when the sensor detects an intensity exceeding the upper threshold value, and wherein radiation emitted by the optical radiation source module at the predefined minimum value serves as measurement radiation for detecting the one or more drying-process characteristics by the sensor.

12. The system of claim 10, wherein the control device is configured to operate the optical radiation source module in a pulse mode, wherein a time-averaged value of an output of the optical radiation source module is reduced when the sensor detects an intensity exceeding the upper threshold value, and wherein radiation emitted by the optical radiation source module during pulses serves as measurement radiation for detecting the one or more drying-process characteristics by the sensor.

13. The system of claim 1,
wherein the sensor, the optical radiation source module, and the control device are integrated into a common module housing, and
wherein the optical radiation source module is a VCSEL module having a plurality of VCSELs, and wherein the control device is part of a VCSEL laser driver integrated into the common module housing.

14. The system of claim 3, wherein the sensor is a spatially resolving sensor configured to detect regions exhibiting stronger reflection of radiation emitted by the optical radiation source module, and wherein the control device is configured to reduce radiation emitted by the optical radiation source module toward the regions exhibiting the stronger reflection.

15. The system of claim 1, wherein the distance between the coated film and the optical radiation source module is greater than 100 mm and less than 200 mm.

16. The system of claim 1, wherein the system further comprises a secondary radiation source configured to emit radiation toward the coated film, and wherein a radiation spectrum of the secondary radiation source is different from a radiation spectrum of the optical radiation source module.

17. The system of claim 1, wherein control of radiation of the optical radiation source module by the control device comprises evaluation and optimization by a machine learning-based artificial intelligence system.

18. The system of claim 1, wherein the drying-process characteristics comprise at least one of drying degree, moisture content, radiation intensity, radiation spectrum, radiation reflection intensity, radiation reflection spectrum, an amount of evaporated solvent, thermal distribution, layer thickness, surface condition, or defects of the coated film.

19. The system of claim 1, wherein the system is configured to recognize an uncoated region of the coated film, and wherein the control device is configured to reduce radiation emitted by the optical radiation source module in the uncoated region.

20. A method for controlling a drying process of a coated film, the method comprising:
detecting one or more drying-process characteristics of the coated film; and
controlling radiation of an optical radiation source module based on the drying-process characteristics.
